(19) United States
(12) Patent Application Publication
(10) Pub. No.: US 2026/0165162 A1
(43) Pub. Date: Jun. 11, 2026

(54) ELECTRONIC PACKAGE AND SUBSTRATE STRUCTURE THEREOF

(71) Applicant: SILICONWARE PRECISION INDUSTRIES CO., LTD., Taichung City (TW)

(72) Inventors: Yi-Wen LIU, Taichung City (TW); Hsiu-Jung LI, Taichung City (TW); Wan-Rou CHEN, Taichung City (TW); Hsin-Yin CHANG, Taichung City (TW); Chih-Chieh SUN, Taichung City (TW)

(73) Assignee: SILICONWARE PRECISION INDUSTRIES CO., LTD., Taichung City (TW)

(21) Appl. No.: 19/052,012

(22) Filed: Feb. 12, 2025

(30) Foreign Application Priority Data
Dec. 9, 2024 (TW) 113147687

(51) Int. Cl. H01L 23/498; H01L 23/00; H01L 25/16

(52) U.S. Cl. CPC H10W 70/65; H10W 90/00; H10W 90/724

(57) ABSTRACT

An electronic package and a substrate structure thereof are provided. The electronic package includes the substrate structure, and an electronic component and a passive component disposed on the substrate structure. A die placement area and a functional area adjacent to each other are defined on a surface of a substrate body of the substrate structure, an area of a metal plate of a wiring layer arranged in the die placement area is reduced, so as to reduce the metal area on the surface of the substrate body to avoid warpage caused by stress concentration in the die placement area.

### BACKGROUND

### 1. Technical Field

The present disclosure relates to a semiconductor packaging technology, and more particularly, to an electronic package and a substrate structure thereof that can improve reliability.

### 2. Description of Related Art

With the development of the electronics industry, nowadays electronic products have tended to be designed in the direction of being light, thin, short and small with diversified functions, semiconductor packaging technology has also developed various types of packaging. In order to meet the high integration and the miniaturization requirements of semiconductor devices, in addition to the traditional wire bonding semiconductor packaging technology, the industry mainly utilizes the flip-chip method to improve the wiring density of semiconductor devices.

FIG. 1A and FIG. 1B are a schematic cross-sectional view and a partial top view, respectively, of a conventional flip-chip semiconductor package 1. As shown in FIG. 1A, a semiconductor chip 11 is bonded to electrical contact pads 104 of a packaging substrate 10 via a plurality of solder bumps 13. The solder bumps 13 are then subjected to reflow soldering. Next, an underfill 14 is formed between the semiconductor chip 11 and the packaging substrate 10 to encapsulate the solder bumps 13.

Furthermore, the packaging substrate 10 is typically configured with at least a passive component 15, such as a capacitor. The passive component 15 is disposed on a single metal plate 100 of the packaging substrate 10 and is electrically connected to the plurality of solder bumps 13 (or the plurality of electrical contact pads 104 as shown in FIG. 1B) of the semiconductor chip 11 via a plurality of conductive traces 101 which are connected to the metal plate 100.

However, in the conventional semiconductor package 1, the metal plate 100 of the packaging substrate 10 is a large-area metal structure, causing the vertical projection area P of the semiconductor chip 11 to overlap the metal plate 100, thereby the distribution area of the metal material of the packaging substrate 10 below the semiconductor chip 11 is too large. Therefore, during temperature cycles or when stress changes, such as passing through a reflow oven or undergoing a drop test, etc., the stress distribution of the packaging substrate 10 is easily uneven due to the mismatch of the coefficient of thermal expansion (CTE) across areas on the surface, resulting in warpage. The warpage (where the warpage direction F1 of the chip is different from the warpage direction F0 of the substrate as shown in FIG. 1A) is prone to separate the plurality of solder bumps 13 from the packaging substrate 10, even causing the solder bumps 13 to be broken. As a result, the electrical connection failures (e.g., open circuits) between the semiconductor chip 11 and the packaging substrate 10 occur, thereby wasting the product and decreasing the product yield.

Therefore, how to overcome the aforementioned problems of the prior art has become an urgent issue to be solved.

### SUMMARY

In view of the aforementioned shortcomings of the prior art, the present disclosure provides a substrate structure, which comprises: a substrate body defined with a die placement area and a functional area adjacent to each other on a surface of the substrate body; and a wiring layer including a plurality of conductive traces arranged inside the die placement area, and a metal plate electrically connected to the plurality of conductive traces and arranged inside the functional area, wherein the metal plate is free from extending to the die placement area, or the metal plate has an opening located at a junction of the die placement area and the functional area.

In the aforementioned substrate structure, the linewidths of the plurality of conductive traces are the same. Alternatively, at least two of the linewidths of the plurality of conductive traces are different.

In the aforementioned substrate structure, a distance between an edge of the die placement area and a metal plate is at least 100 μm.

In the aforementioned substrate structure, the metal plate with the opening located at the junction of the die placement area and the functional area extends to the die placement area.

In the aforementioned substrate structure, the wiring layer further has a plurality of electrical contact pads located in the die placement area and electrically connected to each of the conductive traces. For example, the opening corresponds or does not correspond to a position of one of the electrical contact pads.

In the aforementioned substrate structure, the opening corresponds or does not correspond to a position of one of the conductive traces.

The present disclosure also provides an electronic package, which comprises: the aforementioned substrate structure; an electronic component disposed in the die placement area and electrically connected to the plurality of conductive traces; and a passive component disposed in the functional area and electrically connected to the metal plate.

In the aforementioned electronic package, a distance between an edge of a vertical projection area of the electronic component and the metal plate is at least 100 μm.

It can be seen from the above that, the electronic package and the substrate structure thereof of the present disclosure mainly reduce the area of the wiring layer in the die placement area by the metal plate not extending to the die placement area, or the metal plate having at least an opening, etc. to reduce the metal area on the surface of the substrate body, thereby the electronic package can effectively disperse the stress of the substrate structure, and further prevent the substrate structure from warping. Therefore, compared to the prior art, the present disclosure can prevent the conductive bumps from peeling, thereby facilitating to improve the reliability of the electrical connection between the electronic component and the substrate structure, and further improve the production yield.

### BRIEF DESCRIPTION OF THE DRAWINGS

FIG. 1A is a schematic cross-sectional view of a conventional semiconductor package.

FIG. 1B is a schematic partial top view of the conventional semiconductor package.

FIG. 2A is a schematic cross-sectional view of an electronic package of the present disclosure.

FIG. 2B is a schematic partial top view of the electronic package of the present disclosure.

FIG. 3A, FIG. 3B, and FIG. 3C are schematic top views of other embodiments of an electronic package of the present disclosure.

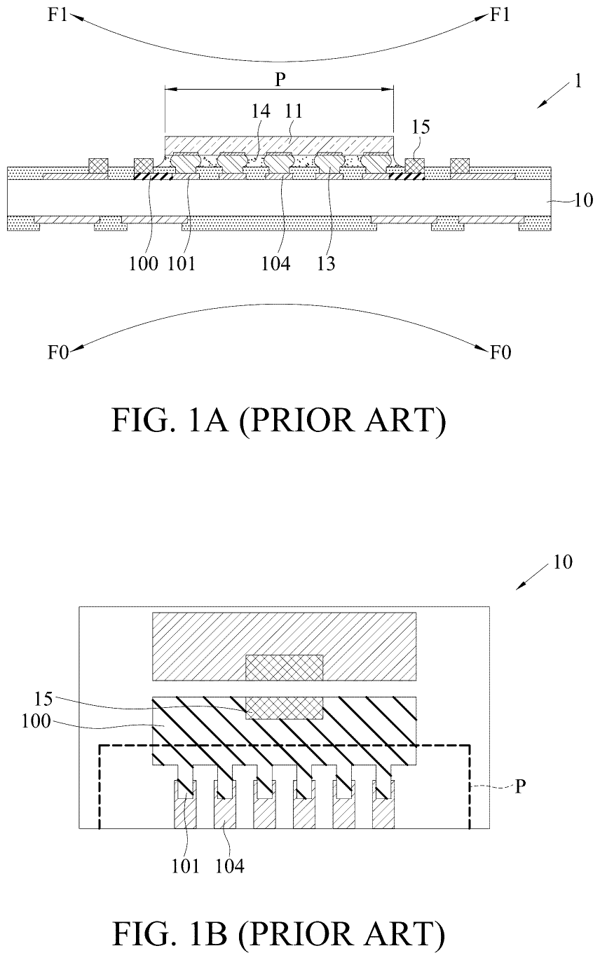

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “under,” “a” and the like are merely for clear explanation rather than limiting the practicable scope of the present disclosure, and thus, alterations or adjustments of the relative relationships thereof without essentially altering the technical contents should still be considered in the practicable scope of the present disclosure.

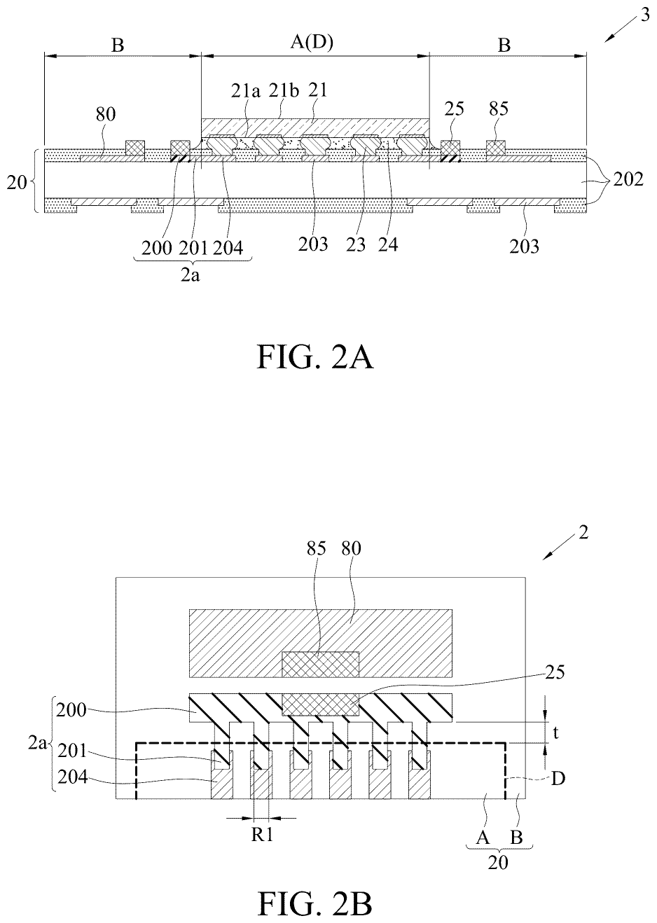

FIG. 2A is a schematic cross-sectional view of an electronic package 3 of the present disclosure, and FIG. 2B is a schematic partial top view of a substrate structure 2 of the present disclosure. As shown in FIG. 2A and FIG. 2B, the substrate structure 2 includes a substrate body 20 and a wiring layer 2a formed on the substrate body 20.

The substrate body 20 is defined with a die placement area A and a functional area B adjacent to each other on a surface of the substrate body 20.

In one embodiment, the substrate body 20 is, for example, a packaging substrate with a core layer or a coreless packaging substrate, which includes a dielectric layer 202 and a circuit layer 203 bonded to the dielectric layer 202 and electrically connected to the wiring layer 2a. For example, the circuit layer 203 and the wiring layer 2a are formed by a redistribution layer (RDL) process, wherein the circuit layer 203 and the wiring layer 2a are made of copper, and the dielectric layer 202 is made of a dielectric material, such as polybenzoxazole (PBO), polyimide (PI), prepreg (PP), etc.

The wiring layer 2a includes a plurality of conductive traces 201 and a metal plate 200 connected to the plurality of conductive traces 201.

In one embodiment, the metal plate 200 is located in the functional area B and outside the die placement area A, and the conductive traces 201 span the die placement area A and the functional area B.

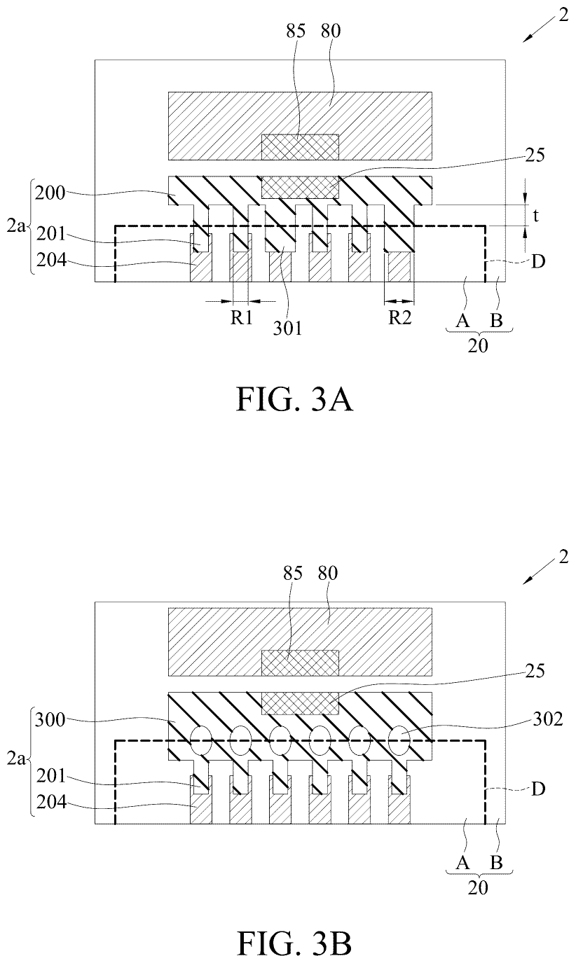

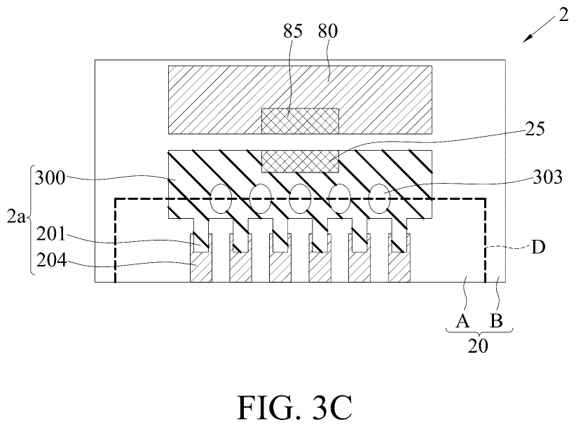

Moreover, the linewidth R1 of each of the conductive traces 201 is the same. Alternatively, as shown in FIG. 3A, at least two of the linewidths R1, R2 of the plurality of conductive traces 201, 301 are different.

In addition, the wiring layer 2a further has a plurality of electrical contact pads 204 located in the die placement area A and electrically connected to each of the conductive traces 201, such that one end of the conductive trace 201 is connected to the metal plate 200, and the other end of the conductive trace 201 is connected to the electrical contact pad 204.

Furthermore, the substrate body 20 is further formed with another metal plate 80 spaced apart from the metal plate 200 in the functional area B.

In the electronic package 3, at least an electronic component 21 is disposed in the die placement area A of the substrate body 20, and at least a passive component (a plurality of passive components 25 and 85 as shown) is disposed in the functional area B of the substrate body 20, such that the electronic component 21 is electrically connected to the passive component 25 via the wiring layer 2a.

The electronic component 21 is an active component such as a semiconductor chip.

In one embodiment, the electronic component 21 has an active surface 21a and an inactive surface 21b opposite to the active surface 21a, and the active surface 21a has a plurality of electrode pads. The electronic component 21 is electrically connected to the circuit layer 203 and the plurality of electrical contact pads 204 via a plurality of conductive bumps 23 containing solder material in a flip-chip manner, and an underfill 24 encapsulates the conductive bumps 23. In other embodiments, the electronic component 21 also can be electrically connected to the circuit layer 203 and the plurality of electrical contact pads 204 via a plurality of solder wires (not shown) in a wire bonding manner. Alternatively, the electronic component 21 can directly contact the circuit layer 203 and the plurality of electrical contact pads 204. It should be understood that there are various ways for the electronic component 21 to be electrically connected to the circuit layer 203 and the plurality of electrical contact pads 204, and are not limited to the above.

Additionally, the distance t between the edge of the die placement area A (or the vertical projection area D of the electronic component 21) and the metal plate 200 is at least 100 μm, e.g., 120 μm.

The passive component 25, 85 is, for example, a resistor, a capacitor, or an inductor, which is disposed on the metal plate 200 and the another metal plate 80, and electrically connected to the metal plate 200 and the another metal plate 80.

Therefore, the electronic package 3 of the present disclosure reduces the area of the metal plate 200 (such as not extending to the die placement area A) through the design of the wiring layer 2a of the substrate structure 2, so as to reduce the metal area (especially the corresponding copper area below the electronic component 21) on the surface of the substrate body 20, so the vertical projection area D (or the die placement area A) of the electronic component 21 does not overlap the metal plate 200. Therefore, compared to the prior art, during temperature cycles or when stress changes, such as during the reflow soldering of the conductive bump 23, the electronic package 3 can effectively disperse the stress of the substrate structure 2 to prevent the stress concentration in the wiring layer 2a, and further to prevent the substrate structure 2 from excessive warping.

In addition, the substrate structure 2 of the present disclosure can avoid the separation between the plurality of conductive bumps 23 and the substrate structure 2 due to warping (even the conductive bump 23 is unable to withstand the stress concentration to be broken). Therefore, the electronic package 3 of the present disclosure facilitates to improve the reliability of the electrical connection between the electronic component 21 and the substrate structure 2, and further can improve the production yield.

Furthermore, the method of reducing the metal area (especially the corresponding copper area below the electronic component 21) on the surface of the substrate body 20 by reducing the area of the metal plate 200 is not limited to the above. As shown in FIG. 3B, even the metal plate 300 spans the die placement area A and the functional area B, the area of the metal plate 200 can be reduced by forming at least an opening 302, 303 on the metal plate 200. The opening 302 corresponds to the position of the conductive trace 201 (or the position of the electrical contact pad 204); alternatively, the opening 303 as shown in FIG. 3C is free from corresponding to the position of the conductive trace 201 (or the position of the electrical contact pad 204); preferably, the opening 302, 303 corresponds to the junction of the die placement area A and the functional area B (or the edge of the vertical projection area D of the electronic component 21).

To sum up, the electronic package and the substrate structure thereof of the present disclosure reduce the metal area on the surface of the substrate body by reducing the area of the wiring layer in the die placement area, thereby the electronic package can effectively disperse the stress of the substrate structure to prevent the substrate structure from warping. Therefore, the present disclosure can prevent the conductive bumps from peeling, thereby facilitating to improve the reliability of the electrical connection between the electronic component and the substrate structure, and further improve the production yield.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A substrate structure, comprising:
a substrate body defined with a die placement area and a functional area adjacent to each other on a surface of the substrate body; and
a wiring layer including a plurality of conductive traces arranged inside the die placement area, and a metal plate electrically connected to the plurality of conductive traces and arranged inside the functional area, wherein the metal plate is free from extending to the die placement area, or the metal plate has an opening located at a junction of the die placement area and the functional area.

2. The substrate structure of claim 1, wherein linewidths of the plurality of conductive traces are the same.

3. The substrate structure of claim 1, wherein at least two of the linewidths of the plurality of conductive traces are different.

4. The substrate structure of claim 1, wherein a distance between an edge of the die placement area and the metal plate is at least 100 μm.

5. The substrate structure of claim 1, wherein the metal plate with the opening located at the junction of the die placement area and the functional area extends to the die placement area.

6. The substrate structure of claim 5, wherein the wiring layer further has a plurality of electrical contact pads located in the die placement area and electrically connected to each of the conductive traces.

7. The substrate structure of claim 6, wherein the opening corresponds to a position of one of the electrical contact pads.

8. The substrate structure of claim 6, wherein the opening is free from corresponding to a position of one of the electrical contact pads.

9. The substrate structure of claim 1, wherein the opening corresponds to a position of one of the conductive traces.

10. The substrate structure of claim 1, wherein the opening is free from corresponding to a position of one of the conductive traces.

11. An electronic package, comprising:
the substrate structure of claim 1;
an electronic component disposed in the die placement area and electrically connected to the plurality of conductive traces; and
a passive component disposed in the functional area and electrically connected to the metal plate.

12. The electronic package of claim 11, wherein a distance between an edge of a vertical projection area of the electronic component and the metal plate is at least 100 μm.

13. The electronic package of claim 11, wherein linewidths of the plurality of conductive traces are the same.

14. The electronic package of claim 11, wherein at least two of the linewidths of the plurality of conductive traces are different.

15. The electronic package of claim 11, wherein a distance between an edge of the die placement area and the metal plate is at least 100 μm.

16. The electronic package of claim 11, wherein the metal plate with the opening located at the junction of the die placement area and the functional area extends to the die placement area, and wherein the wiring layer further has a plurality of electrical contact pads located in the die placement area and electrically connected to each of the conductive traces.

17. The electronic package of claim 16, wherein the opening corresponds to a position of one of the electrical contact pads.

18. The electronic package of claim 16, wherein the opening is free from corresponding to a position of one of the electrical contact pads.

19. The electronic package of claim 11, wherein the opening corresponds to a position of one of the conductive traces.

20. The electronic package of claim 11, wherein the opening is free from corresponding to a position of one of the conductive traces.
